(19) United States
(12) Patent Application Publication
(10) Pub. No.: US 2026/0005031 A1
(43) Pub. Date: Jan. 1, 2026

(54) System and Method for Improving Atomic Layer Etching Performance

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/758,955

(22) Filed: Jun. 28, 2024

(51) Int. Cl. H01L 21/3065; C23C 14/34; C23C 14/54; G05B 19/4099; H01J 37/32; H01J 37/34

(52) U.S. Cl. CPC H01L 21/30655; C23C 14/345; C23C 14/54; G05B 19/4099; H01J 37/321; H01J 37/32449; H01J 37/32926; H01J 37/34; G05B 2219/45031; H01J 2237/332; H01J 2237/3341

(57) ABSTRACT

Disclosed herein are systems and methods for enhancing atomic layer etching (ALE) in semiconductor manufacturing. It focuses on eliminating reactive ion etching (RIE) components during the surface modification step, a key challenge in conventional ALE processes. By integrating a switch mechanism for a blocking capacitor in a path between a bias unit and a chuck, this method significantly improves etching precision and efficiency. The invention can be readily extended to other etching or deposition applications, wherein a surface modification is required without ion interactions with a substrate surface.

### BACKGROUND OF THE INVENTION

### 1. Field of the Invention

This invention relates to the field of semiconductor manufacturing, with a specific focus on enhancing atomic layer etching (ALE) processes. The primary objective is to refine ALE techniques by effectively eliminating reactive ion etching (RIE) components that typically occur during a surface modification step. This advancement is particularly significant for the precise fabrication of microelectronic devices where control at the atomic scale is crucial. The invention aims to optimize the ALE process, ensuring higher fidelity and accuracy in etching, which is essential to produce advanced integrated circuits, memory devices, sensors, and other semiconductor components.

### 2. Description of the Prior Art

RIE is a predominant technology in semiconductor manufacturing. In RIE, diverse species including neutrals, radicals, and ions concurrently influence the etching process. A key characteristic of RIE is the synergistic interaction between ion and neutral fluxes, which significantly enhances the etching rate. This synergistic effect was first described by Coburn and Winters in “Ion- and electron-assisted gas-surface chemistry—an important effect in plasma etching,” published in J. Appl. Phys., vol. 50, pages 3189-3196 (1979). They reported increased silicon etching rates when using an argon ion beam, a XeF2 neutral beam, and their combination. Further, Gottscho et al., in “Microscopic uniformity in plasma etching” (J. Vac. Sci. Technol., B10, pages 2133-2147, 1992), developed a model to quantify this synergy for the etching rate ER:

$$ER = \frac{{vE}_{i} {J}_{i}}{1 + ( v {E}_{i} {J}_{i} ) / ( {v}_{n} {sJ}_{n )}} ,$$

where u represents the volume removed per unit bombardment energy for a saturated surface (cm³/eV), Eᵢ the ion energy (eV), Jᵢ the ion flux to the surface (cm²/s), uₙ the volume removed per reacting neutral (cm³), Jₙ the neutral flux to the surface and s the sticking probability of the neutral species on the bare surface.

Achieving effective RIE necessitates the presence of both ion and neutral fluxes to exploit the synergy identified by Coburn and Winters. However, it is increasingly complex in modern etching apparatus to balance these fluxes, particularly for etching high aspect ratio structures with dimensions shrinking to nanometer scale. Uniform results across 300 mm wafers and consistent repeatability in production pose additional challenges.

Over the past several decades, advancements in etching apparatus features have been made to enhance uniformity. For instance, the evolution of plasma sources from a single coil (U.S. Pat. No. 4,948,458 to Ogle) to multiple coils (U.S. Pat. No. 6,164,241 to Chen et al.) has been notable, either in the form of inductively coupled plasma (ICP) or transformer coupled plasma (TCP). Additionally, gas injection techniques have been improved, incorporating multiple injection points to ensure a uniform plasma within the vacuum reactor, as described in U.S. Pat. No. 8,231,799 to Bera et al. and U.S. Pat. No. 10,825,659 to Treadwell. Further enhancements include optimizing the electrostatic chuck (ESC) to feature multiple zones with independently adjustable temperatures (U.S. Pat. No. 9,713,200 to Pease and U.S. Pat. No. 10,056,225 to Gaff et al.).

A radio frequency (RF) power generator, coupled to the ESC, provides a bias for the ions in the plasma in addition to the plasma sheath. This coupling, facilitated through a blocking capacitor, helps establish a stable plasma sheath by preventing electron flow to the ground, as detailed in U.S. Pat. No. 5,302,240 to Hori et al. Moreover, various pulsing schemes for RF power generators have been implemented to improve ion energy and angular momentum distribution, thereby maximizing the synergetic effects between ions and neutrals, as described in U.S. Pat. No. 8,264,154 to Banner et al. and U.S. Pat. No. 10,121,639 to Kanarik. RF power generators with tailored waveforms, as discussed by Wang et al. in “Experimental demonstration of multifrequency impedance matching for tailored voltage waveform plasmas” (J. Vac. Sci. Technol. A37, 021303, pages 1-11, 2019), have also been employed to precisely control ion energy. Additionally, gases can be pulsed in a cyclic process to enhance performance, as disclosed in U.S. Pat. No. 10,121,639 to Kanarik. This cyclic approach segments the RIE process into steps, each optimized with a different set of process gases.

Despite these improvements, achieving the required uniformity across a 300 mm wafer for critical dimension (CD), loading, and profile remains a significant challenge, often entailing considerable expense.

ALE has been developed to address the limitations of RIE. ALE apparatus has evolved from the RIE apparatus with less stringent requirements for achieving uniformity on a 300 mm wafer. However, ALE has unique requirements due to the nature of its process steps, detailed herein.

An overview of ALE technology is presented by Karanik et al. in “Overview of atomic layer etching in the semiconductor industry” (J. Vac. Sci. Technol. A33, pages 020802 1-14, 2015), and further discussed in a book by Lill, “Atomic layer processing: semiconductor dry etching technology” (Wiley-VCH GmbH, Boschstr. 12, 69469 Weinheim, Germany, 2021). ALE facilitates the controlled removal of material layers with atomic-level precision and is characterized as an etching technique using sequential self-limiting reactions. The basic ALE process includes two steps: surface modification and material removal. The modification creates a thin reactive layer with a defined thickness, which is easier to remove than the unmodified material. The removal step eliminates this modified layer while preserving the underlying substrate, thus resetting the surface for subsequent cycles. The material removal is quantified over multiple cycles and can be achieved using thermal energy by raising the wafer's temperature or kinetic energy from ions typically derived from inert gases. The isotropic process using thermal energy to remove modified layers is described in U.S. Pat. No. 10,208,383 to George et al. When utilizing energetic ions, the removal is conducted via a sputtering process.

The anisotropic ALE process, which is the focus of the present invention, has been employed for etching various materials, demonstrating the technology's versatility:
Si and Ge as described in U.S. Pat. No. 10,727,073 to Tan et al.,
SiO2 as described in U.S. Pat. No. 9,620,382 to Oehrlein et al.,
C as described in U.S. Pat. Pub. Nos. 2017/0316935 and 2022/0216050 by Tan et al.,
W as described in U.S. Pat. Pub. No. 2020/0286743 from Lai et al and U.S. Pat. No. 10,096,487 to Yang et al,
Co as described in U.S. Pat. No. 10,096,487 to Yang et al,
Ru as described in U.S. Pat. Pub. No. 2022/0199422 by Yang et al.,
Other refractory metals and materials with high surface binding energy as described in U.S. Pat. No. 11,450,513 to Yang et al.,
Cu as described in WO Pat. Pub. No. 2022/046429 by Yang et al.,
GaN and other III-V materials as described in U.S. Pat. No. 10,056,264 to Yang et al.,
MRAM as described in U.S. Pat. No. 10,749,103 to Tan et al.,
EUV patterning as described in U.S. Pat. No. 9,922,839 to Wise et al., and
Surface smoothing of various materials as described in U.S. Pat. No. 10,304,659 to Karanik et al.

The distinct chemistry, speciation, and plasma energy composition involved in the surface modification and sputtering steps enhance the process by enabling more controlled ion, electron, and neutral species fluxes, thereby widening the process window. This separation facilitates self-limiting reactions, crucial for maintaining the ideality of the etching process-characterized by uniformity, smoothness, and selectivity. Karanik et al. in “Predicting synergy in atomic layer etching” (J. Vac. Sci. Technol. A35, pages 05C302 1-7, 2017) defined ALE synergy as:

$${ALE}_{synergy} S ( \% ) = \frac{EPC - ( α + β )}{EPC} \times 100 \%$$

EPC is “etch per cycle” representing the total thickness of material removed in one cycle, typically averaged over many cycles. The values of “a” and “B” are (undesirable) contributions from the surface modification step and the sputtering step, respectively. Ideally, synergy will approach 100% with no etching from either step alone. In practice, RIE in the surface modification step are nonzero because of presence of ions in the plasma which generates neutrals to modify the surface. In the sputtering step, physical sputtering of underlying unmodified layer is also nonzero.

It is desirable for the plasma in the surface modification step of the ALE process to be free from ion bombardment. However, the unintended introduction of RIE components during this step presents a persistent challenge. This issue stems from the difficulty in completely preventing ion bombardment of the substrate surface, compromising the ideality of the ALE processes. Modern ALE methodologies struggle to effectively eliminate these RIE components, leading to suboptimal etching outcomes, particularly as device geometries become more complex and smaller in scale. The presence of RIE components in ALE processes can result in non-uniform layer removal and undesirable etching profiles, which are especially problematic in advanced device manufacturing where even minor deviations can significantly impact device performance and yield.

One solution to this problem, as disclosed in U.S. Pat. No. 9,362,131 to Agarwal et al., involves using an electron beam source. During the passivation step (surface modification step), a remote plasma source supplies passivation species to the main process chamber while keeping ion energy below the etching threshold. During the etching operations, the flow from the remote plasma source is stopped, and the ion energy is raised above the etch threshold. This approach introduces an additional remote source, complicating the apparatus, it may increase the cost of the process.

The present invention addresses this critical gap in ALE technology by introducing an improved method that effectively eliminates the RIE component from the surface modification step. This method enables a more controlled and precise etching process, thereby enhancing the quality and consistency of the semiconductor devices produced. This novel approach represents a significant advancement in semiconductor fabrication, promising to support the ongoing development of smaller, more complex, and higher-performing electronic devices.

### SUMMARY

The present invention introduces significant advancements in the ALE process, specifically targeting the elimination of RIE components during the surface modification step. The invention encompasses several embodiments and implementations to address this challenge effectively.

In one embodiment, the invention utilizes a switch mechanism, such as a parallel switch, to bypass the blocking capacitor at surface modification step of the ALE. This bypassing prevents the formation of a plasma sheath, thereby mitigating ion bombardment on the substrate surface and effectively eliminating the RIE component during the surface modification step. At the sputtering step, the blocking capacitor is switched back to a path between a bias unit and a chuck, which enables establishing a bias for accelerating of ions in an inert gas plasma.

In some other embodiments, the switch can be placed in series with the blocking capacitors. The switch can be implemented by a transistor, or a relay controlled by a signal from the controller.

In one implementation, a controller focuses on the operational synchronization between the switch and the plasma source. In some implementations, the invention involves a preemptive activation of the switch, occurring ahead of the plasma source's or the bias unit's activation. This approach ensures that the conditions conducive to RIE component generation are negated before the neutrals are introduced to modify the substrate surface.

In some implementations, the switch may float the chuck during the surface modification step instead of grounding the chuck.

It is important to note that the scope of the invention is not confined to the specific examples and embodiments disclosed herein. For example, in another embodiment, a tailored waveform generator can be employed as the bias unit without a blocking capacitor. For such an implementation, a switch can be used to disconnect the tailored waveform generator from the chuck during the surface modification step while it is connected to the chuck during the sputtering step.

The ALE process system is used for illustration of the inventive concept only. The invention can be deployed for any plasma-based applications or process systems, wherein a surface modification is required without ion interactions with the surface of a substrate undergoing processing inside the chamber. Examples include but are not limited to an RIE, a radical based etching, and a plasma enhanced deposition.

The invention is open to other modifications and variations as would be apparent to a person skilled in the art. Therefore, the invention is to be limited only by the scope and spirit of the claims appended hereto.

### BRIEF DESCRIPTIONS OF DRAWINGS

In order to provide enhanced clarity, the following description references the accompanying drawings:

FIG. 1A illustrates an embodiment of a process system for ALE with a switchable blocking capacitor.

FIG. 1B illustrates another embodiment of a process system for ALE with a switchable tailored waveform generator.

FIG. 2 presents a flowchart of the ALE process enabled by the exemplary process system.

### DETAILED DESCRIPTIONS

To ensure comprehensive understanding, this section delves into detailed embodiments of the present invention. Although certain specifics are provided for clarity, modifications and variations that align with the subsequent claims are deemed appropriate. Conventional methods and components are highlighted to underscore the distinct features of the invention.

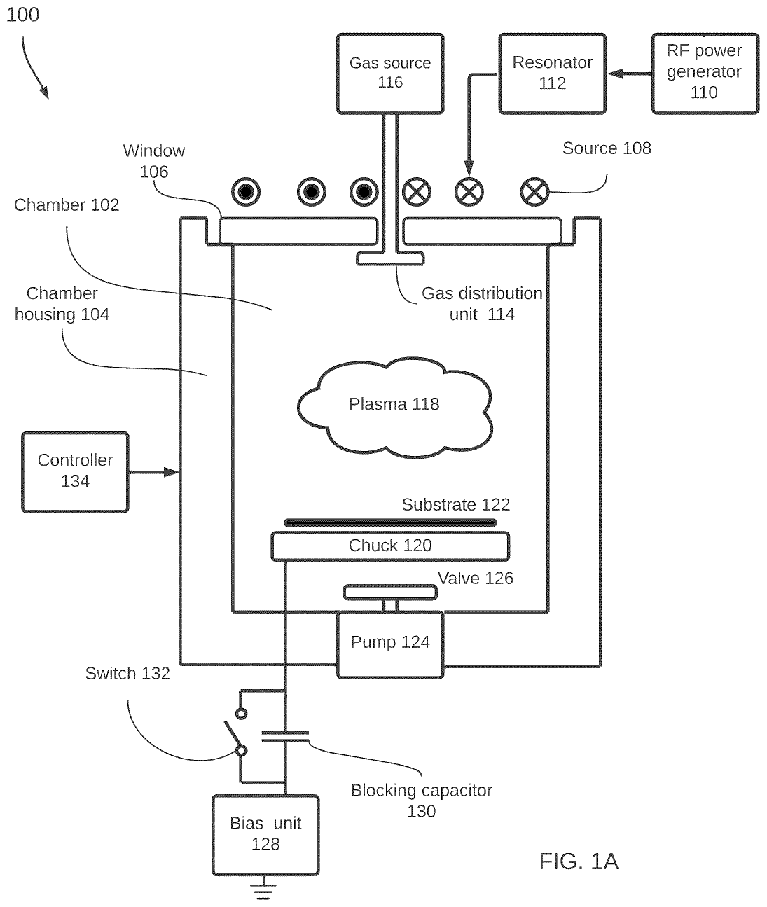

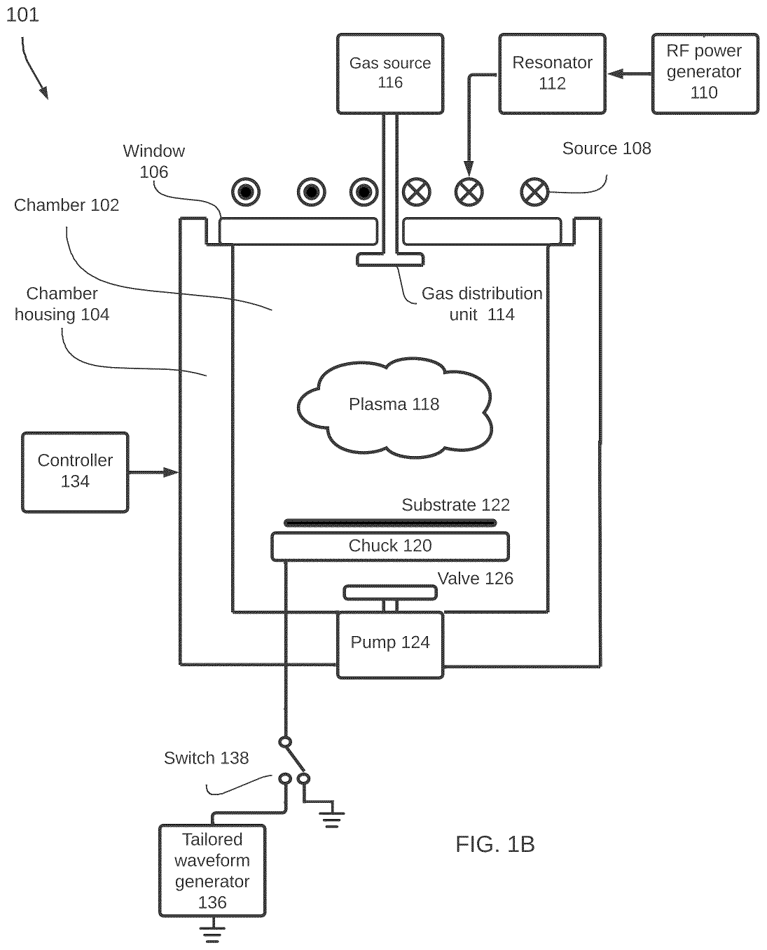

FIG. 1A presents an embodiment of an ALE process system, labeled as 100, which incorporates a plasma process chamber, marked as 102. The operations within the process chamber are coordinated by a controller, denoted as 134. The chamber (102) is enclosed by a chamber housing, indicated as 104, creating a vacuum environment conducive to plasma processing operations. This chamber housing (104) may be composed of materials such as aluminum or quartz. The interior surface of the aluminum may undergo specific treatments to enhance its resistance to the harsh plasma environment. For instance, this surface can be anodized or coated with an yttrium oxide layer.

Affixed atop the chamber housing (104) is a window, designated as 106, which hermetically seals chamber 102. In some embodiments, this window consists of quartz, while in others, it is made from other plasma-resistant materials. The interior surface of the window (106) can be coated with a plasma-resistant material like an yttrium oxide layer. Positioned above the window 106 is a plasma source, identified as 108. As depicted in FIG. 1, the plasma source includes a three-turn coil, but it's important to note that the coil could vary in the number of turns or consist of multiple coils, depending on specific operational needs, and may adopt various shapes, such as cylindrical or conical.

The plasma source (108) is functionally linked to a radio frequency (RF) power generator, denoted as 110, through a resonator, indicated as 112. The RF power generator (110) can produce RF power at single or multiple frequencies, including but not limited to 100 kHz, 200 kHz, 400 kHz, 2 MHz, 13.56 MHz, 27 MHz, 40 MHz, and 60 MHz. The resonator (112) matches the output impedance of the RF power generator (110) with the plasma load of chamber (102), considering the impact of transmission lines.

A gas distribution unit, referred to as 114, connects to a gas source, marked as 116, via an aperture in the window (106). Maintaining a hermetic seal of this aperture is crucial to preserve the vacuum integrity of chamber (102). The gas source (116) may include various delivery units for gases, such as a gasbox. Depending on the specific embodiment, the gas distribution unit (114) can function as either an injector or a showerhead. In some configurations, the window (106) integrates with the gas distribution unit (114), acting as a showerhead while also sealing the chamber (102).

Also integrated within chamber (102) is a chuck, identified as 120, serving as the support structure for a substrate, indicated as 122. The chuck (120) may take various forms, including, but not limited to, an ESC or a vacuum chuck. The chamber (102) is coupled to a pump (124) and an associated valve (126). The pump (124) removes unused gases and reaction byproducts from the chamber (102). The set point of valve (126), in conjunction with the capacity of pump (124), determines the withdrawal rate of the gases and byproducts.

In the art, a blocking capacitor, numbered 130, is typically used to prevent passing of direct current (DC) signals. This blocking capacitor (130) plays a vital role in establishing a stable plasma sheath above the processed substrate in chamber (102). After plasma 118 is ignited, electrons, ions, and neutrals are generated, with electrons moving much faster than ions and neutrals. These electrons accumulate on surfaces, creating a negative potential known as the plasma sheath. The blocking capacitor (130) stops electrons from moving to the ground, enabling the buildup of this negative potential.

In the exemplary case as shown in FIG. 1A, the process system (100) integrates a parallel switch, numbered 132, with the blocking capacitor 130. Upon closing of the switch (132), the chuck (120) is grounded through the bias unit (128). When the switch (130) is open, the blocking capacitor (130) is functioning normally.

In some other implementations, a two-way switching may be used to connect the chuck (120) either to ground or to the bias unit (128) via the blocking capacitor (130). It should be noted that there are various variations in switching the blocking capacitor (130). In some implementations, a switching can be coupled in series with the blocking capacitor (130). Upon opening of the switch, the chuck (120) is floating.

At the surface modification step, the switch (132) bypasses the blocking capacitor (130), preventing the formation of a sheath and thereby eliminating the RIE component in this step. During the sputtering step, the switch (132) is open, allowing the blocking capacitor to be activated. The established bias then accelerates ions from the plasma (118). The operation of switch (132) is controlled by sending signals from the controller (134) to the switch (132). The switch (132) can be a transistor, such as a power MOSFET, or a relay controlled by an electrical signal, encompassing various forms as known in the art.

FIG. 1B showcases another embodiment, denoted as 101, where a tailored waveform generator 136 is employed to provide a bias for the chuck 120. The tailored waveform generator can enable tighter ion energy distribution, which is important for advanced etching process, particularly for a high aspect ratio structure formation. The tailored waveform generator 136 operates typically in much lower frequency than the RF power generator for the plasma source. A blocking capacitor is not essential for its operations. In this embodiment, a two-way switch 138 can be used to switch off the bias during the surface modification step, by grounding the chuck 126. The switch 138 will activate the tailored waveform generator 136 during the sputtering step.

An ALE process system is used as an example to illustrate the present inventive concept. The invention can be readily extended to other process systems such as for example an RIE process system or a radical based etching process system, wherein a surface modification step is desirable without ion interaction with a surface of the substrate being processed.

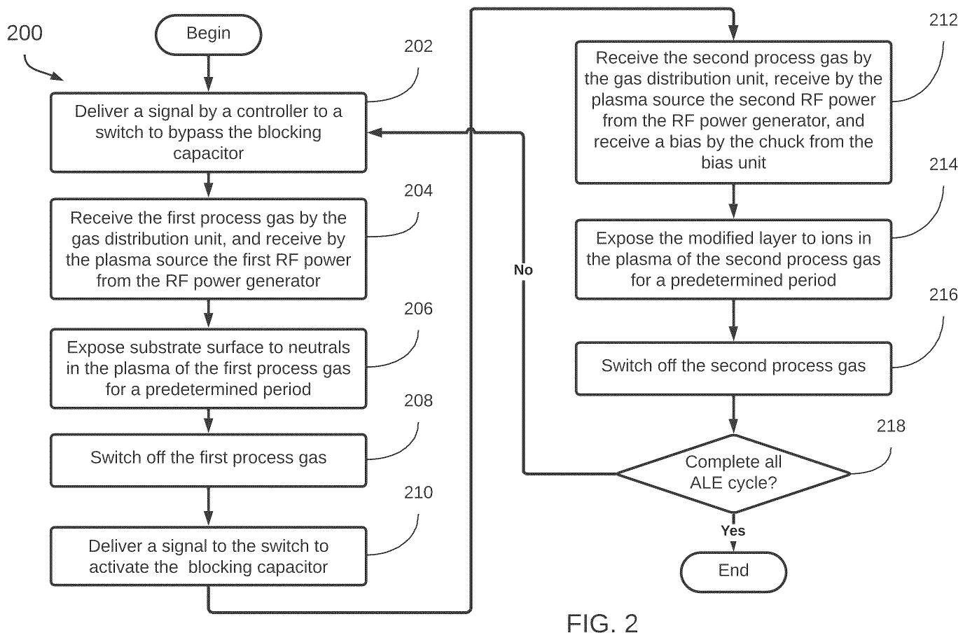

A flowchart for the ALE process, marked as 200, is depicted in FIG. 2. The process 200 commences with step 202, where a signal is sent from the controller (134) to the switch (132) to close the parallel switch (132), thereby bypassing the blocking capacitor (130). At step 204, the first process gas is received by the gas distribution unit (114) from the gas source (116). Typically, this first process gas comprises a halogen element, such as chlorine, particularly for silicon ALE. Once a steady state chamber pressure is established, as measured by a manometer (not shown in the figures), the plasma source (108) begins receiving the first RF power from the RF power generator (110). The chamber pressure can range from 1 mTorr to 500 mTorr, and the RF power may vary from 50 to 5000 watts. The plasma (118) is ignited, producing electrons, neutrals, and ions. The neutrals, including radicals, diffuse to the substrate's surface (122) and modify one or several monolayers. Due to the absence of the blocking capacitor (130), the chuck is grounded, preventing the formation of a plasma sheath, and consequently eliminating ion bombardment of the surface. In one implementation, the moment that the switch (132) is closed synchronizes with the activation of the plasma source (108). Alternatively, the blocking capacitor (130) might be bypassed at a predetermined time before the plasma source (108) is activated.

At step 206, the substrate's surface (122) undergoes modification for a predetermined duration, completing the surface modification step of the ALE process. This duration may range from 50 ms to 10 s. Subsequently, at step 208, the first gas is deactivated by the controller (134).

Step 210 involves the switch (132) receiving another signal from the controller (134) to reactivate the blocking capacitor (130), preparing for the sputtering step. The parallel switch (132) is then opened.

At step 212, the second process gas is delivered to the gas distribution unit (114) from the gas source (116). This second gas typically includes, but is not limited to, inert gases like argon, xenon, krypton, or helium. Once a steady state chamber pressure is achieved, typically lower than that during the surface modification step, the plasma source (108) begins receiving the second RF power from the RF power generator (110). For the sputtering step, the bias unit (128) supplies additional power to the chuck (124) and establishes a bias in addition to the plasma sheath. This accelerates ions towards the substrate's surface to remove the modified layer formed during the surface modification step. Various implementations may use pulsing techniques for the plasma source (108) and/or the bias unit (128), with these pulses being synchronized, asynchronized, or following different modulation frequencies. The plasma source (108) can receive RF power ranging from 10 to 5000 watts. The bias unit (128) may supply power generating a bias voltage for the substrate ranging from 50 to 1500 volts.

At step 214, the modified surface layer is sputtered off by exposing the substrate surface to ions for a predetermined period, which can range from 10 ms to 10 s. Following this, at step 216, the second process gas is deactivated, thereby concluding one ALE cycle, comprising both the surface modification and sputtering steps.

Finally, at step 218, the controller (134) checks whether all the ALE cycles are completed. If not, the ALE cycle is repeated.

1. An ALE process system, comprising:
a chamber maintaining an interior space for a vacuum environment;
a plasma source coupled to an RF power generator configured to generate plasma in the chamber;
a bias unit operatively connected to a chuck through a blocking capacitor for blocking DC signals, wherein the blocking capacitor is further coupled to a switch, wherein the switch can either bypass or activate the blocking capacitor;
a gas distribution unit configured to receive at least one gas from a gas source and distribute the received gas to the chamber; and
a controller configured to operate the process system in steps including a surface modification step and a sputtering step sequentially, wherein in the surface modification step, the controller operates the switch to bypass the blocking capacitor, and in the sputtering step, the controller operates the switch to activate the blocking capacitor.

2. The process system of claim 1, wherein the gas distribution unit is operated by the controller to receive a first process gas from the gas source for the surface modification step and to receive a second process gas from the gas source for the sputtering step.

3. The process system of claim 1, wherein the controller is further configured to operate the process system with a step of switching off the first process gas before the sputtering step.

4. The process system of claim 1, wherein the controller is further configured to operate the process system with a step of switching off the second process gas before the surface modification step.

5. The process system of claim 1, wherein the plasma source further includes a TCP source.

6. The process system of claim 1, wherein the plasma source further includes an ICP source.

7. The process system of claim 1, wherein the RF power generator is coupled to the plasma source through a resonator.

8. The process system of claim 1, wherein the bias unit further includes an RF power generator.

9. The process system of claim 1, wherein the bias unit is operated to generate a bias for the chuck during the sputtering step.

10. A method of performing an ALE process in a process system, comprising:
operating by a controller the process system in a surface modification step with a first process gas, wherein a blocking capacitor in a path between a bias unit and a chuck is bypassed by a switch upon receiving a signal from the controller; and
operating by the controller the process system in a sputtering step with a second process gas, wherein the blocking capacitor is activated upon receiving a signal from the controller.

11. The method of claim 10, wherein the method further includes a step of switching off the first process gas between the surface modification step and the sputtering step.

12. The method of claim 10, wherein the method further includes a step of switching off the second process gas between the sputtering step and the surface modification step.

13. The method of claim 10, wherein the method further includes operating the switch at a time according to a predetermined algorithm.

14. The method of claim 13, wherein said predetermined algorithm further includes programming by the controller a time difference between bypassing the blocking capacitor and receiving an RF power by a plasma source from an RF power generator.

15. The method of claim 13, wherein said predetermined algorithm further includes programming by the controller a time difference between activating the blocking capacitor and switching on the bias unit.

16. The method of claim 10, wherein the switch further includes a transistor, or a relay controlled by an electrical signal from the controller.

17. A process system, comprising:
a chamber maintaining an interior space for a vacuum environment;
a plasma source coupled to an RF power generator configured to generate plasma in the chamber; and
a bias unit operatively connected to a chuck through a switch, wherein the bias unit is disconnected from the chuck by a controller using the switch when a process, being conducted in the chamber, desires no ion bombardment on a substrate, wherein the chuck is grounded after the bias unit is disconnected.

18. The process system of claim 17, wherein the bias unit is a tailored waveform generator.

19. The process system of claim 17, wherein the process system further includes an ALE process system.

20. The process system of claim 17, wherein the process system further includes an RIE process system, a radical based etching process system, and a deposition process system.
